(19) United States
(12) Patent Application Publication
(10) Pub. No.: US 2025/0301670 A1
(43) Pub. Date: Sep. 25, 2025

(54) METAL-INSULATOR-METAL CAPACITOR STRUCTURE

(71) Applicant: INTERNATIONAL BUSINESS MACHINES CORPORATION, ARMONK, NY (US)

(72) Inventors: Ruilong Xie, Niskayuna, NY (US); Joshua M. Rubin, Albany, NY (US); Qianwen Chen, Chappaqua, NY (US); Tao Li, Slingerlands, NY (US); Chih-Chao Yang, Glenmont, NY (US)

(21) Appl. No.: 18/609,127

(22) Filed: Mar. 19, 2024

(51) Int. Cl. H01L 23/522

(52) U.S. Cl. CPC H10D 1/042; H01L 23/5223; H10D 1/716

(57) ABSTRACT

A metal-insulator-metal (MIM) capacitor includes a plurality of metal pillars formed on an underlying layer. The MIM capacitor also includes a first dielectric layer formed on the metal pillars, a first type metal layer formed on the first dielectric layer, a second dielectric layer formed on the first type metal layer, a second type metal layer formed on the second dielectric layer, a first electrode electrically connected to the second type metal layer, and a second electrode electrically connected to the first type metal layer.

### BACKGROUND

The present disclosure relates to the electrical, electronic and computer fields. In particular, the present disclosure relates to metal-insulator-metal (MIM) capacitors having different plate structures. Typically, the MIM capacitor has a sandwich structure and can be described as a parallel plate capacitor. The capacitor top metal (CTM) is separated from the capacitor bottom metal (CBM) by a thin insulating dielectric layer.

MIM capacitors may be used in high performance applications in complementary metal-oxide-semiconductor (CMOS) technology. For example, MIM capacitors have been used in functional circuits such as mixed signal circuits, analog circuits, radio frequency (RF) circuits, dynamic random access memory (DRAM), embedded DRAM, and logic operation circuits. In system-on-chip (SOC) applications, different capacitors for different functional circuits have to be integrated on a same chip to serve different purposes. For example, in mixed signal circuits, capacitors are used as decoupling capacitors and high-frequency noise filters. For DRAM and embedded DRAM circuits, capacitors are used for memory storage. However, for RF circuits, capacitors are used in oscillators and phase-shift networks for coupling and/or bypassing purposes. For microprocessors, capacitors may be used for decoupling. The high frequency and low power of semiconductor chips may require a large number of decoupling capacitors. MIM capacitors have been used for decoupling in certain of these applications.

### SUMMARY

Certain embodiments relate to a metal-insulator-metal (MIM) capacitor. The MIM capacitor includes a plurality of metal pillars formed on an underlying layer. The MIM capacitor also includes a first dielectric layer formed on the metal pillars, a first type metal layer formed on the first dielectric layer, a second dielectric layer formed on the first type metal layer, a second type metal layer formed on the second dielectric layer, a first electrode electrically connected to the second type metal layer, and a second electrode electrically connected to the first type metal layer.

Certain embodiments relate to an integrated circuit device including a metal-insulator-metal (MIM) capacitor. The MIM capacitor includes a plurality of metal pillars formed on an underlying layer. The MIM capacitor also includes a first dielectric layer formed on the metal pillars, a first type metal layer formed on the first dielectric layer, a second dielectric layer formed on the first type metal layer, a second type metal layer formed on the second dielectric layer, a first electrode electrically connected to the second type metal layer, and a second electrode electrically connected to the first type metal layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a cross-sectional view of an example MIM capacitor device at an intermediate stage of the manufacturing process.

FIG. 2 is a cross-sectional view of the MIM capacitor device of FIG. 1 after additional fabrication operations, according to embodiments.

FIG. 3 is a cross-sectional view of the MIM capacitor device of FIG. 2 after additional fabrication operations, according to embodiments.

FIG. 4 is a cross-sectional view of the MIM capacitor device of FIG. 3 after additional fabrication operations, according to embodiments.

FIG. 5 is a cross-sectional view of the MIM capacitor device of FIG. 4 after additional fabrication operations, according to embodiments.

FIG. 6 is a cross-sectional view of the MIM capacitor device of FIG. 5 after additional fabrication operations, according to embodiments.

FIG. 7 is a cross-sectional view of the MIM capacitor device of FIG. 6 after additional fabrication operations, according to embodiments.

FIG. 8 is a cross-sectional view of the MIM capacitor device of FIG. 7 after additional fabrication operations, according to embodiments.

FIG. 9 is a cross-sectional view of the MIM capacitor device of FIG. 8 after additional fabrication operations, according to embodiments.

FIG. 10 is a cross-sectional view of the MIM capacitor device of FIG. 9 after additional fabrication operations, according to embodiments.

FIG. 11 is a cross-sectional view of the MIM capacitor device of FIG. 10 after additional fabrication operations, according to embodiments.

It should be appreciated that elements in the figures are illustrated for simplicity and clarity. Well-understood elements that may be useful or necessary in a commercially feasible embodiment may not be shown for the sake of simplicity and to aid in the understanding of the illustrated embodiments.

### DETAILED DESCRIPTION

The present disclosure describes metal-insulator-metal (MIM) capacitor devices and methods of manufacturing MIM capacitor devices. In particular, the present disclosure describes MIM capacitor devices that include multiple metal layers separated by insulating layers, where the various layers are formed in a serpentine pattern over a plurality of different metal pillar, and where the manufacturing process utilizes subtractive metal patterning operations.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, a MIM capacitor refers to a capacitor having a stacked structure, for example, including a bottom electrode, a top electrode, and an insulator therebetween. More specifically, a MIM capacitor is commonly used in high performance applications in CMOS technology. Typically, the MIM capacitor has a sandwich structure and can be described as a parallel plate capacitor. The capacitor top metal (CTM) is separated from the capacitor bottom metal (CBM) by a thin insulating dielectric layer. Both parallel plates are typically formed from TiN that are patterned and etched through the use of several photolithography photomasking steps. The thin insulating dielectric layer is typically made from silicon oxide, silicon nitride, or high K dielectric materials, such as Al₂O₃, HfO₂, ZrO₂ or a combination of these, deposited by chemical vapor deposition (CVD), for example. Certain of the present embodiments describe MIM capacitors having more than the traditional three plates (i.e., a first metal layer, an insulator layer, and a second metal layer). For example, certain of the present embodiments describe four and five plate MIM capacitors.

As discussed herein, the high frequency and the low power of semiconductor chips may require a large number of decoupling capacitors. MIM capacitors have been used for decoupling in these applications. These capacitors can take up valuable chip area and impact the overall size of the chip. The present embodiments provide a MIM capacitor structure with a reduced footprint and an increased density.

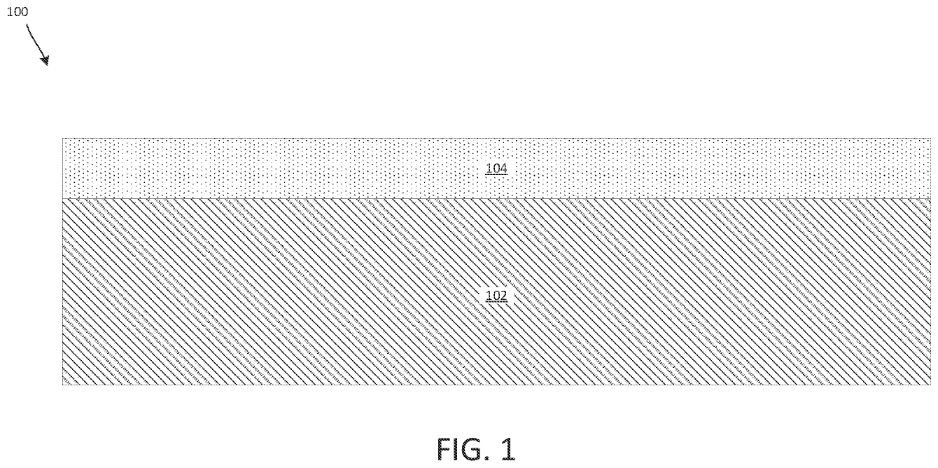

Referring now to the drawings in which like numerals represent the same or similar elements and initially to FIG. 1, an example semiconductor device 100 is shown that includes an underlying layer 102. The underlying layer 102 may be part of a back-end-of-line (BEOL) structure and may include various interconnects and/or other devices such as transistors. In general, logic chips can be subdivided into several separate regions: the front-end-of-line (FEOL), the middle-of-line (MOL) and the back-end-of-line (BEOL). The FEOL covers the processing of the active parts of the chips (i.e., the transistors that reside on the bottom of the chip). The FEOL and the BEOL are tied together by the MOL. The MOL is typically made up of tiny metal structures that serve as contacts to the transistor's source, drain and gate. These structures connect to the local interconnect layers of the BEOL. The BEOL, the final stage of processing, refers to the interconnects that reside in the top part of the semiconductor device 100. In general, interconnects are complex wiring schemes that distribute clock and other signals, provide power and ground and transfer electrical signals from one transistor to another. As mentioned above, the BEOL may include the underlying layer shown in FIG. 1. The BEOL generally includes a plurality of different metal layers, local (Mx) layers, intermediate layers, and wiring layers. As shown in FIG. 1, an Mx layer 104 is formed on the underlying layer, and this Mx layer 104 may be a part of the overall BEOL structure. The total number of Mx layers 104 in the BEOL can be as many as 15 or more, while the typical number of Mx layers 104 ranges between 3 and 6. Each of these layers contains metal lines and dielectric materials, which are interconnected vertically by means of via structures that are filled with metal. It should be appreciated that the combination of the underlying layer 102 and the Mx layer 104 may be considered as a starting structure upon which the MIM capacitors may be built, and each of these layers may include a plurality of different sublayers.

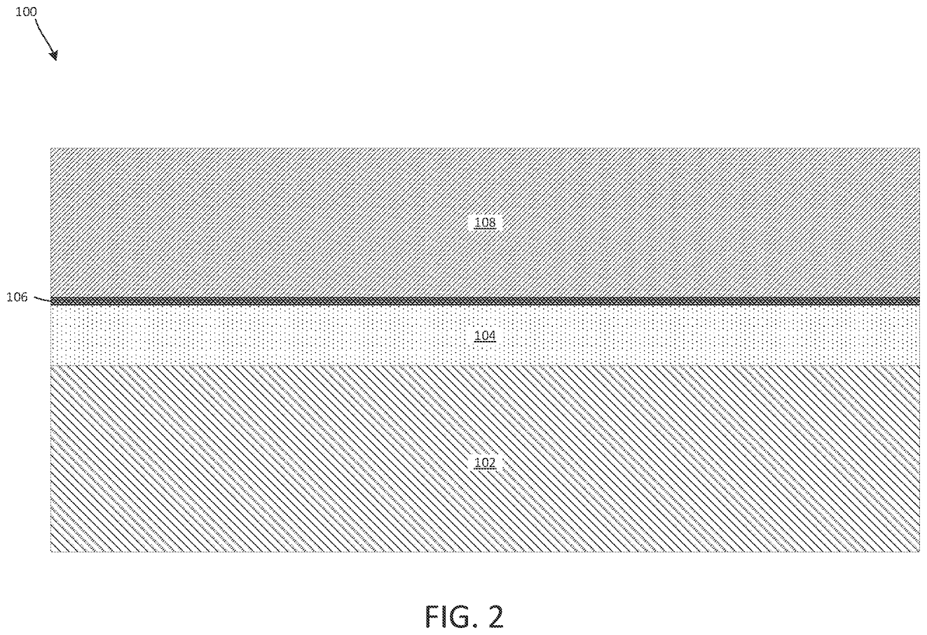

Referring now to FIG. 2, this figure is a cross-sectional view of the semiconductor device 100 of FIG. 1 after additional fabrication operations, according to embodiments. As shown in FIG. 2, a liner layer 106 is formed on the Mx layer 104. In certain examples, the liner layer 106 may include Ta, TaN, Ti, TiN, TiSiN, W, Ru or combinations thereof. In one example, the liner layer 106 is between about 5 nm and about 100 nm thick. Then, a metal layer is deposited that will subsequently be patterned into metal pillars 108. The metal pillars 108 may comprise, for example, Ru or another suitable metal.

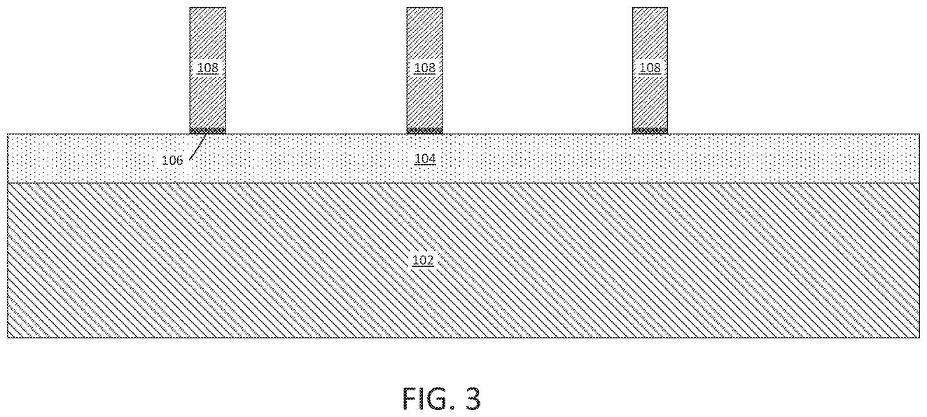

Referring now to FIG. 3, this figure is a cross-sectional view of the semiconductor device 100 of FIG. 2 after additional fabrication operations, according to embodiments. As shown in FIG. 3, a subtractive metal patterning operation is performed to remove portions of the metal pillars 108 and the liner layer 106. These materials are removed down to the level of the Mx layer 104. Thus, the material removal operations form the various metal pillars 108. In one example, reactive ion etching (RIE) is used to remove the material of the metal pillars 108 and liner layer 106.

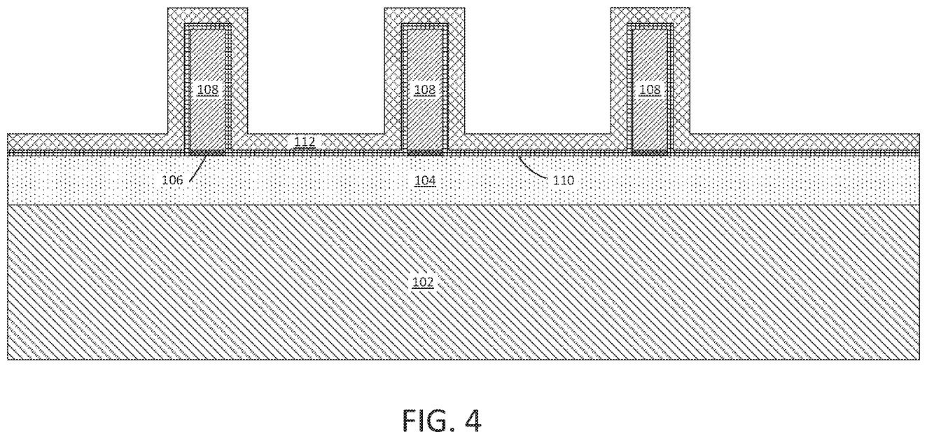

Referring now to FIG. 4, this figure is a cross-sectional view of the semiconductor device 100 of FIG. 3 after additional fabrication operations, according to embodiments. As shown in FIG. 4, a high-κ dielectric layer 110 is conformally deposited over the entire surface of the wafer. The conformal first high-κ dielectric layer 110 comprises a high-κ dielectric material. In general, the term high-κ refers to a material with a high dielectric constant (κ, kappa), as compared to silicon dioxide. High-κ dielectrics may be used in semiconductor manufacturing processes where they are usually used to replace a silicon dioxide gate dielectric or another dielectric layer of a device. In MIM capacitor devices, such as the one shown in FIG. 4, the high-κ layer 110 functions as an insulating layer that may be sandwiched between different metal layers (or electrodes) to form a part of the MIM capacitor device. Thus, the term high-κ as used herein refers to a material having a relative dielectric constant κ which is much higher than that of silicon dioxide (e.g., a dielectric constant κ=25 for hafnium oxide (HfO₂) rather than 4 for silicon dioxide). Examples of suitable high-κ gate dielectric materials include, but are not limited to, HfO₂, Al₂O₃, ZrO₂ and/or lanthanum oxide (La₂O₃). Due to the presence of the metal pillars 108, the high-κ layer 110 follows a winding (or generally serpentine) path over and around the metal pillars 108. This allows for an increased total surface area of the high-κ layer 110 relative to a case where the high-κ layer is a planar layer. This increase in overall surface area of the high-κ layer 110 due to the presence of the metal pillars 108 will allow for an increased density of MIM capacitors and a reduced overall footprint. As also shown in FIG. 4, a first type metal layer 112 is conformally formed on the high-κ layer 110. The first type metal layer 112 may comprise, for example, TiN. However, it should be appreciated that other materials may be used for the first type metal layer 112 provided that they have etching selectivity with respect to the chose materials for the second type metal layer 114, as discussed in further detail below. The first type metal layer 112 functions as one of the electrodes in the MIM capacitor.

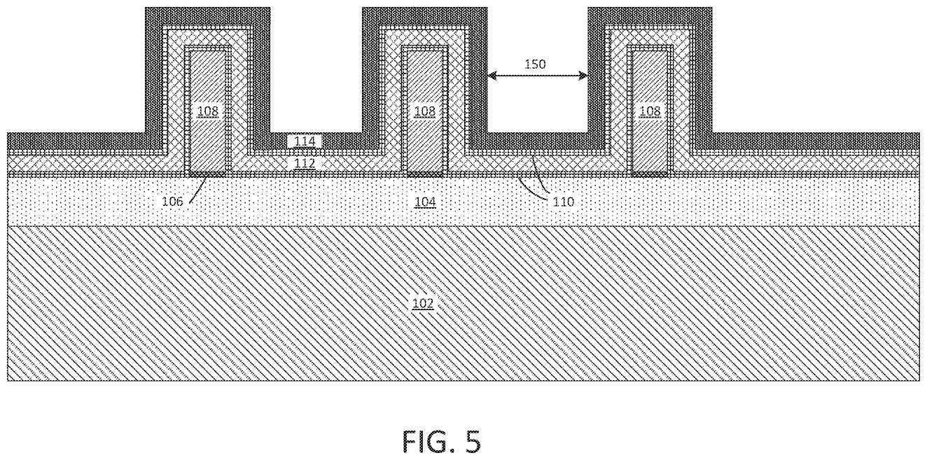

Referring now to FIG. 5, this figure is a cross-sectional view of the semiconductor device 100 of FIG. 4 after additional fabrication operations, according to embodiments. As shown in FIG. 5, another high-κ layer 110 is formed on the first type metal layer 112. Then, a second type metal layer 114 is formed on the additional high-κ layer 110. In certain embodiments, the second type metal layer 114 comprises TiAlC. In the embodiments described herein, the material of the second type metal layer 114 should be different from the material of the first type metal layer 112 to allow for etching selectivity between these layers. For example, the material of the first type metal layer 112 could be TiAlC when the material of the second type metal layer is TiN. In general, “selectivity” (or etching selectivity) means that a first element can be etched while the second element can act as an etch stop. Thus, in the example given above, a first etchant may be used to selectively etch the first type metal layer 112 without significantly removing material of the second type metal layer 114. Also, a second etchant (that is different than the first etchant) may be used to selectively etch the second type metal layer 114 without significantly removing material of the first type metal layer 112. Thus, as will be explained in further detail below, this will allow for first type electrical contacts to connect to the first type metal layers 112 on a first side of the semiconductor device 100 (e.g., the left side), and for second type electrical contacts to connect to the second type metal layers 114 on a second side of the semiconductor device 100 (e.g., the right side). Further, similar to the high-κ layers 110, the first type metal layers 112 and second type metal layers 114 follow the contours of the metal pillars 108, which allow for an increased surface area of the MIM capacitor device, and this enables an increase in the device density and a reduction in the footprint of the MIMCAPs. As additional layers (i.e., high-κ layers and metal layers) are formed, the unfilled space 150 between adjacent metal pillars 108 is gradually filled in with the additional material.

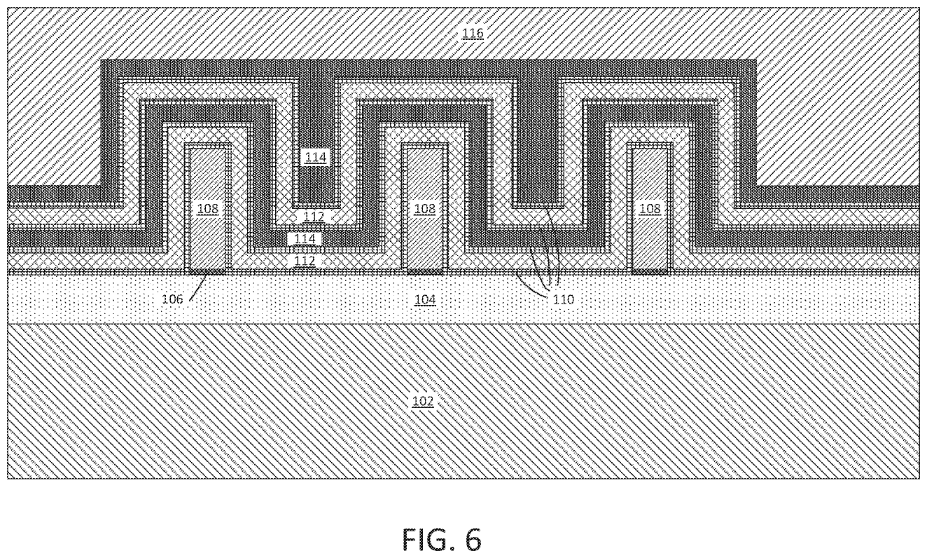

Referring now to FIG. 6, this figure is a cross-sectional view of the semiconductor device 100 of FIG. 5 after additional fabrication operations, according to embodiments. As shown in FIG. 6, the processes described above with respect to FIGS. 4 and 5 are repeated until the unfilled space 150 is completely filled in with material. That is, additional alternating layers of the first type metal layer 112 and the second type metal layer 114 are formed (i.e., with additional high-κ layers 110 formed between each of the respective metal layers) until the space between the metal pillars 108 is filled up. In certain examples, the alternating layers could be formed of alternative materials other than that listed above, as long as there is overall etching selectivity between the first type metal layers 112 and the second type metal layers 114. That is, the different ones of the first type metal layer 112 could have different material compositions as long as they all share an etching selectivity characteristic that allows them to be etched selective to the second type metal layers 114. The same idea would apply to the second type metal layers 114. It should be appreciated that in other embodiments, a plurality of alternating layers of the first type metal layer 112 and the second type metal layer 114 can be formed without completely filling up the unfilled space 150. In these embodiments, any remaining unfilled space 150 may be filled with a dielectric layer or another suitable planarization layer. In certain examples, after the unfilled space 150 is filled in with the alternating layers of the first type metal layer 112 and the second type metal layer 114 and the high-κ layers, an optional planarization process (e.g., CMP) may be performed to planarize the exposed top surface of the uppermost second type metal layer 114. It should also be appreciated that the total number of layers of the first type metal layers 112, the high-κ layers 110 and the second type metal layers 114 may be different than the example shown in FIG. 6.

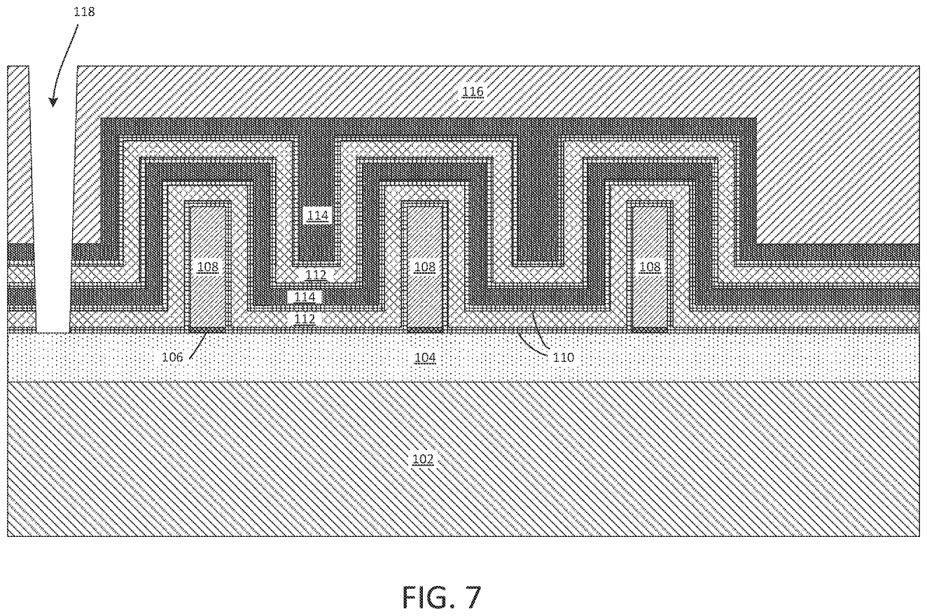

Referring now to FIG. 7, this figure is a cross-sectional view of the semiconductor device 100 of FIG. 6 after additional fabrication operations, according to embodiments. As shown in FIG. 7, an interlayer dielectric (ILD) layer 116 is formed over the uppermost second type metal layer 114. Then, a suitable material removal process is used to form a first trench 118 in the semiconductor device 100. As shown in FIG. 7, the first trench 118 is formed down to the level of the Mx layer 104. The first trench 118 will allow for subsequent formation of a first electrode (e.g., a bottom electrode) that will connect to the second type metal layers 114. It should be appreciated that any suitable material removal process may be used (e.g., RIE) to form the first trench 118.

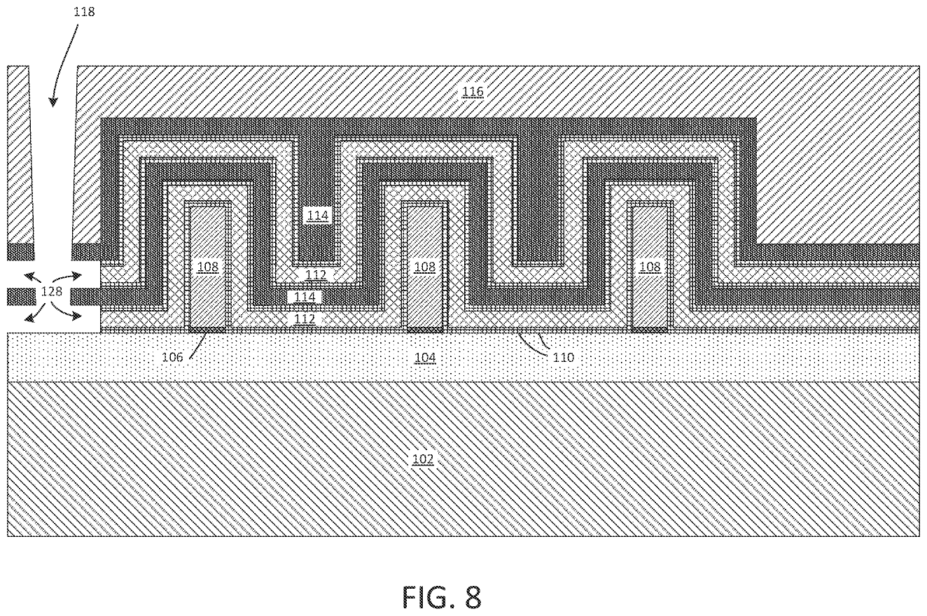

Referring now to FIG. 8, this figure is a cross-sectional view of the semiconductor device 100 of FIG. 7 after additional fabrication operations, according to embodiments. As shown in FIG. 8, a suitable material removal process such as etching is performed to selectively recess the exposed first type metal layers 112 (and optionally the high-κ metal layers 110, as shown in FIG. 8) to form first recessed areas 128. It should be appreciated that a suitable etchant may be selected that selectively etches the material of the first metal layers 112 without significantly removing material of the second metal layers 114.

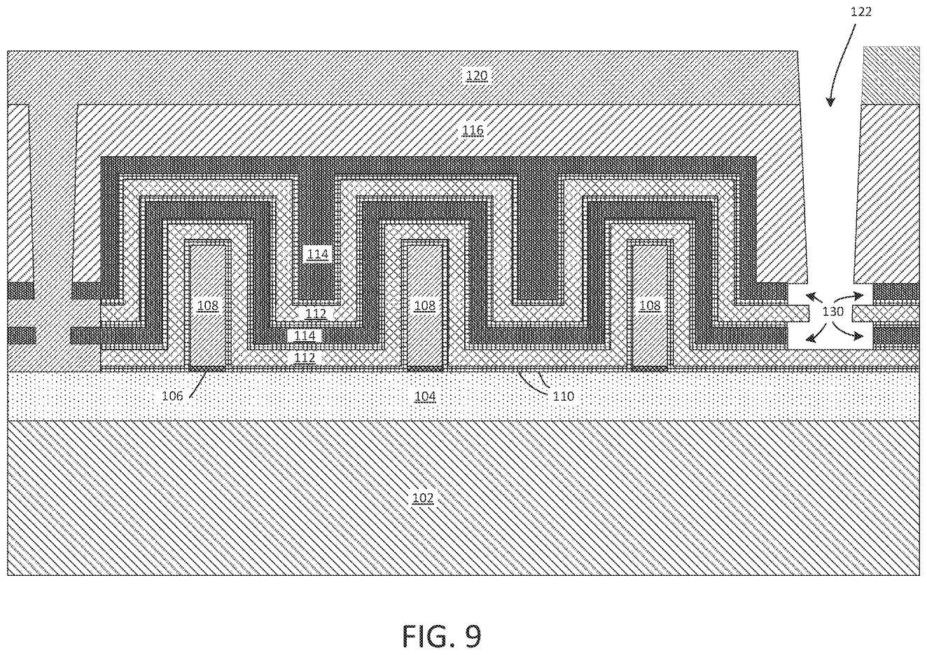

Referring now to FIG. 9, this figure is a cross-sectional view of the semiconductor device 100 of FIG. 8 after additional fabrication operations, according to embodiments. As shown in FIG. 9, an organic planarization (OPL) layer 120 is formed on the semiconductor device 100 to fill in the first trench 118 and the first recessed areas 128, and to cover the ILD layer 116. Then, a suitable material removal process is used to form a second trench 122 in the semiconductor device 100. As shown in FIG. 9, the second trench 122 is formed down to the level of the lowest first metal layer 112 (i.e., as opposed to etching down to the Mx layer 104 as was described above with respect to FIG. 7). This may be accomplished with a timed etching process that is designed to end when the lowest first type metal layer 112 is reached. The second trench 122 will allow for subsequent formation of a second electrode (e.g., a top electrode) that will connect to the first type metal layers 112 (i.e., as opposed to connecting to the second type metal layers 114 as was described above with respect to FIG. 7). It should be appreciated that any suitable material removal process may be used (e.g., RIE) to form the second trench 122. Then, as shown in FIG. 9, a suitable material removal process such as etching is performed to selectively recess the exposed second type metal layers 114 (and optionally the high-κ metal layers 110, as shown in FIG. 9) to form second recessed areas 130. It should be appreciated that a suitable etchant may be selected that selectively etches the material of the second metal layers 114 without significantly removing material of the first metal layers 112.

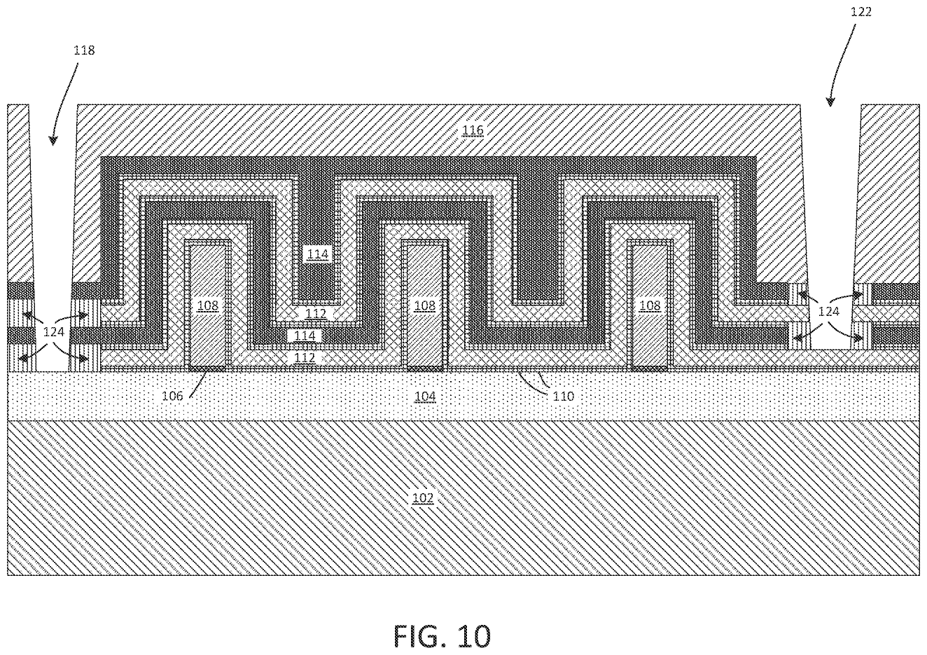

Referring now to FIG. 10, this figure is a cross-sectional view of the semiconductor device 100 of FIG. 9 after additional fabrication operations, according to embodiments. As shown in FIG. 10, the OPL layer 120 is removed. Then, a suitable material deposition operation is performed to form inner spacers 124 in the first recessed areas 128 and the second recessed areas 130. The inner spacers 124 may comprise one or more suitable insulating materials. Therefore, on the left side of the semiconductor device 100 near the first trench 118, the side surfaces of the first type metal layers 112 are covered with the insulating inner spacer 124 material. However, on this left side, the second type metal layers 114 are still exposed. Moreover, on the right side of the semiconductor device 100 near the second trench 122, the side surfaces of the second type metal layers 114 are covered with the insulating inner spacer 124 material. However, on this right side, the first type metal layers 112 are still exposed. The inner spacer 124 is formed by a conformal dielectric deposition followed by isotropic etching back process.

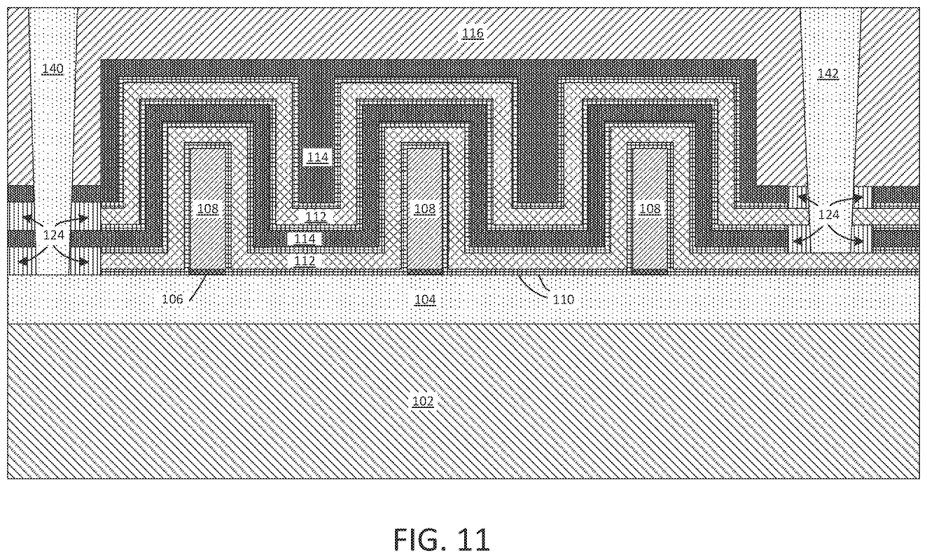

Referring now to FIG. 11, this figure is a cross-sectional view of the semiconductor device 100 of FIG. 10 after additional fabrication operations, according to embodiments. As shown in FIG. 10, a first electrode 140 (e.g., a bottom electrode) is formed in the first trench 118. The first electrode 140 is electrically connected to the second type metal layers 114, but the first electrode 140 is not electrically connected to the first type metal layers 112 due to the presence of the inner spacers 124. Also, a second electrode 142 (e.g., a top electrode) is formed in the second trench 122. The second electrode 142 is electrically connected to the first type metal layers 112, but the second electrode 142 is not electrically connected to the second type metal layers 114 due to the presence of the inner spacers 124. Thus, a multilayer MIM capacitor is formed with several electrically connected alternating layers of metal, insulator and metal. Due to the presence of the metal pillars 108 and the winding (or serpentine) shapes of the metal and insulator layers (i.e., first type metal layers 112, high-κ layers 110 and second type metal layers 114), a total surface area of the MIMCAP device may be increased (i.e., relative to the case where are the layers are planar), thus enabling an increase in device density while reducing the overall footprint of the capacitors.

Some embodiments of the present disclosure can take the form of a metal-insulator-metal (MIM) capacitor. The MIM capacitor includes a first dielectric layer in a serpentine pattern on an underlying layer, a first type metal layer formed on the first dielectric layer, a second dielectric layer formed on the first type metal layer, a second type metal layer formed on the second dielectric layer, a first electrode electrically connected to the second type metal layer, and a second electrode electrically connected to the first type metal layer. Forming the various metal layers and dielectric layers on the metal pillars may allow for an increase in increase in surface areas of these layers, which minimized an overall footprint of the MIM capacitor. This may allow for an increase in device density for an integrated circuit device including a plurality of the MIM capacitors, while maintaining performance characteristics of same.

In some examples of the MIM capacitor, the MIM capacitor includes an Mx layer formed between the underlying layer and the MIM capacitor. The Mx layer contains metal lines and dielectric materials, which are interconnected vertically by means of via structures, and this enables an integrated circuit device to be formed that connects the MIM capacitor to the Mx layer.

In some examples of the MIM capacitor, a bottom surface of the first electrode contacts the Mx layer, and a bottom surface of the second electrode contacts the first type metal layer. Forming the first electrode and the second electrode to different depts may allow for the first electrode to electrically connect with only the second type metal layers and the second electrode to electrically connect with only the first type metal layers.

In some examples of the MIM capacitor, the first type metal layer has a different etching selectivity relative to the second type metal layer. This may allow for the use of different etchants to be used in material removal processing steps that have different etching selectivities to the first and second metal layers. This is turn may allow the formation of the inner spacers at different electrode levels.

In some examples of the MIM capacitor, the MIM capacitor further includes a pillar formed between the underlying layer and the first, and the first dielectric layer, the first type metal layer, the second dielectric layer and the second type metal layer have the serpentine pattern resulting from the respective layers being formed to surround the pillar. Forming the various metal layers and dielectric layers on the metal pillars is this serpentine shape may allow for an increase in increase in surface areas of these layers, which minimized an overall footprint of the MIM capacitor. This may allow for an increase in device density for an integrated circuit device including a plurality of the MIM capacitors, while maintaining performance characteristics.

In some examples of the MIM capacitor, the MIM capacitor further includes a plurality of the first type metal layers alternating with a plurality of the second type metal layers, wherein the dielectric layers are present between each of the respective first type metal layers and second type metal layers. This allows for stacking of multiple conductive layers within the MIM capacitor device, which may allow for a decreased overall footprint of the MIM capacitors, while maintaining performance characteristics.

In some examples of the MIM capacitor, the first electrode is connected to the plurality of second type metal layers, and the second electrode is connected to the plurality of first type metal layers. This allows for the first and second electrode to be connected to alternating conductive metal layers within the MIM capacitor.

In some examples of the MIM capacitor, the MIM capacitors include a plurality of the pillars. The first type metal layers, the second type metal layers and the dielectric layers completely fill an area between adjacent ones of the pillars. This may allow for formation of a maximum number of alternating first and second type metal layers within the MIM capacitor, which may allow for a decreased overall footprint of the MIM capacitors, while maintaining performance characteristics.

In some examples of the MIM capacitor, a topmost one of the second type metal layers has a planar upper surface in the area between the metal pillars. This may allow for formation of a maximum number of alternating first and second type metal layers within the MIM capacitor, which may allow for a decreased overall footprint of the MIM capacitors, while maintaining performance characteristics.

In some examples of the MIM capacitor, the MIM capacitor further includes a first inner spacer formed between the first electrode and the first type metal layer, and a second inner spacer formed between the second electrode and the second type metal layer. When the inner spacers are formed from a dielectric material, this allows for the first electrode to be electrically isolated from the first type metal layers, and the second electrode to be electrically isolated from the second type metal layers.

In some examples of the MIM capacitor, the first type metal layer comprises TiN, and the second type metal layer comprises TiAlC. This may allow for the use of different etchants to be used in material removal processing steps that have different etching selectivities to the first and second metal layers. This is turn may allow the formation of the inner spacers at different electrode levels.

Some embodiments of the present disclosure can take the form of an integrated circuit device that includes a BEOL layer and a metal-insulator-metal (MIM) capacitor. The MIM capacitor includes a first dielectric layer formed in a serpentine pattern on an underlying layer, a first type metal layer formed on the first dielectric layer, a second dielectric layer formed on the first type metal layer, a second type metal layer formed on the second dielectric layer, a first electrode electrically connected to the second type metal layer, and a second electrode electrically connected to the first type metal layer. Forming the various metal layers and dielectric layers on the metal pillars may allow for an increase in increase in surface areas of these layers, which minimized an overall footprint of the MIM capacitor. This may allow for an increase in device density for an integrated circuit device including a plurality of the MIM capacitors, while maintaining performance characteristics of same.

In some examples of the integrated circuit device, the MIM capacitor includes an Mx layer formed between the underlying layer and the MIM capacitor. The Mx layer contains metal lines and dielectric materials, which are interconnected vertically by means of via structures, and this enables an integrated circuit device to be formed that connects the MIM capacitor to the Mx layer.

In some examples of the integrated circuit device, a bottom surface of the first electrode contacts the Mx layer, and a bottom surface of the second electrode contacts the first type metal layer. Forming the first electrode and the second electrode to different depts may allow for the first electrode to electrically connect with only the second type metal layers and the second electrode to electrically connect with only the first type metal layers.

In some examples of the integrated circuit device, the first type metal layer has etching selectivity relative to the second type metal layer. This may allow for the use of different etchants to be used in material removal processing steps that have different etching selectivities to the first and second metal layers. This is turn may allow the formation of the inner spacers at different electrode levels.

In some examples of the integrated circuit device, the MIM capacitor includes a pillar formed between the underlying layer and the first dielectric layer. The first dielectric layer, the first type metal layer, the second dielectric layer and the second type metal layer have the serpentine pattern resulting from the respective layers being formed to surround the pillar. Forming the various metal layers and dielectric layers on the metal pillars is this serpentine shape may allow for an increase in increase in surface areas of these layers, which minimized an overall footprint of the MIM capacitor. This may allow for an increase in device density for an integrated circuit device including a plurality of the MIM capacitors, while maintaining performance characteristics.

In some examples of the integrated circuit device, the MIM capacitor further includes a plurality of the first type metal layers alternating with a plurality of the second type metal layers, wherein the dielectric layers are present between each of the respective first type metal layers and second type metal layers. This allows for stacking of multiple conductive layers within the MIM capacitor device, which may allow for a decreased overall footprint of the MIM capacitors, while maintaining performance characteristics.

In some examples of the integrated circuit device, the first electrode is connected to the plurality of second type metal layers, and the second electrode is connected to the plurality of first type metal layers. This allows for the first and second electrode to be connected to alternating conductive metal layers within the MIM capacitor.

In some examples of the integrated circuit device, the MIM capacitor further includes a plurality of the pillars. The first type metal layers, the second type metal layers and the dielectric layers completely fill an area between adjacent ones of the pillars. This may allow for formation of a maximum number of alternating first and second type metal layers within the MIM capacitor, which may allow for a decreased overall footprint of the MIM capacitors, while maintaining performance characteristics.

In some examples of the integrated circuit device, a topmost one of the second type metal layers has a planar upper surface in the area between the metal pillars. This may allow for formation of a maximum number of alternating first and second type metal layers within the MIM capacitor, which may allow for a decreased overall footprint of the MIM capacitors, while maintaining performance characteristics.

In some examples of the integrated circuit device, the MIM capacitor further includes a first inner spacer formed between the first electrode and the first type metal layer, and a second inner spacer formed between the second electrode and the second type metal layer. When the inner spacers are formed from a dielectric material, this allows for the first electrode to be electrically isolated from the first type metal layers, and the second electrode to be electrically isolated from the second type metal layers.

In some examples of the integrated circuit device, the first type metal layer comprises TiN, and the second type metal layer comprises TiAlC. These materials may allow for the use of different etchants to be used in material removal processing steps that have different etching selectivities to the first and second metal layers. This is turn may allow the formation of the inner spacers at different electrode levels.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A metal-insulator-metal (MIM) capacitor comprising:
a first dielectric layer formed in a serpentine pattern on an underlying layer;
a first type metal layer formed on the first dielectric layer;
a second dielectric layer formed on the first type metal layer;
a second type metal layer formed on the second dielectric layer;
a first electrode electrically connected to the second type metal layer; and
a second electrode electrically connected to the first type metal layer.

2. The MIM capacitor of claim 1, further comprising an Mx layer formed between the underlying layer and the MIM capacitor.

3. The MIM capacitor of claim 2, wherein a bottom surface of the first electrode contacts the Mx layer, and a bottom surface of the second electrode contacts the first type metal layer.

4. The MIM capacitor of claim 1, wherein the first type metal layer is a different type relative to the second type metal layer.

5. The MIM capacitor of claim 1, further comprising a pillar formed between the underlying layer and the first dielectric layer, wherein the first dielectric layer, the first type metal layer, the second dielectric layer and the second type metal layer have the serpentine pattern resulting from being formed to surround the pillar.

6. The MIM capacitor of claim 1, further comprising a plurality of the first type metal layers alternating with a plurality of the second type metal layers, wherein the first dielectric layer and second dielectric layer are present between each of the respective first type metal layers and second type metal layers.

7. The MIM capacitor of claim 6, wherein the first electrode is connected to the plurality of second type metal layers, and the second electrode is connected to the plurality of first type metal layers.

8. The MIM capacitor of claim 6, further comprising a plurality of the pillars, wherein the first type metal layers, the second type metal layers and the dielectric layers completely fill an area between adjacent ones of the pillars.

9. The MIM capacitor of claim 8, wherein a topmost one of the second type metal layers has a planar upper surface with a non-serpentine pattern in the filled area between the pillars.

10. The MIM capacitor of claim 1, further comprising a first inner spacer formed between the first electrode and the first type metal layer, and a second inner spacer formed between the second electrode and the second type metal layer.

11. An integrated circuit device comprising:
a back-end-of-line (BEOL) layer including an underlying layer; and
a metal-insulator-metal (MIM) capacitor formed on the BEOL layer, the MIM capacitor including,
a first dielectric layer formed in a serpentine pattern on the underlying layer,
a first type metal layer formed on the first dielectric layer,
a second dielectric layer formed on the first type metal layer,
a second type metal layer formed on the second dielectric layer,
a first electrode electrically connected to the second type metal layer, and
a second electrode electrically connected to the first type metal layer.

12. The integrated circuit device of claim 11, further comprising an Mx layer formed between the underlying layer and the MIM capacitor.

13. The integrated circuit device of claim 12, wherein a bottom surface of the first electrode contacts the Mx layer, and a bottom surface of the second electrode contacts the first type metal layer.

14. The integrated circuit device of claim 11, wherein the first type metal layer is a different type relative to the second type metal layer.

15. The integrated circuit device of claim 11, further comprising a pillar formed between the underlying layer and the first dielectric layer, wherein the first dielectric layer, the first type metal layer, the second dielectric layer and the second type metal layer have the serpentine pattern resulting from being formed to surround the pillar.

16. The integrated circuit device of claim 11, further comprising a plurality of the first type metal layers alternating with a plurality of the second type metal layers, wherein the first dielectric layer and second dielectric layer are present between each of the respective first type metal layers and second type metal layers.

17. The integrated circuit device of claim 16, wherein the first electrode is connected to the plurality of second type metal layers, and the second electrode is connected to the plurality of first type metal layers.

18. The integrated circuit device of claim 16, further comprising a plurality of the pillars, wherein the first type metal layers, the second type metal layers and the dielectric layers completely fill an area between adjacent ones of the pillars.

19. The integrated circuit device of claim 18, wherein a topmost one of the second type metal layers has a planar upper surface with a non-serpentine pattern in the filled area between the pillars.

20. The integrated circuit device of claim 11, further comprising a first inner spacer formed between the first electrode and the first type metal layer, and a second inner spacer formed between the second electrode and the second type metal layer.
